(19) United States
(12) Patent Application Publication
(10) Pub. No.: US 2024/0006449 A1
(43) Pub. Date: Jan. 4, 2024

(54) SOLID-STATE IMAGING ELEMENT, MANUFACTURING METHOD, AND ELECTRONIC APPARATUS

(71) Applicant: SONY SEMICONDUCTOR SOLUTIONS CORPORATION, Kanagawa (JP)

(72) Inventor: Junichiro FUJIMAGARI, Kanagawa (JP)

(73) Assignee: SONY SEMICONDUCTOR SOLUTIONS CORPORATION, Kanagawa (JP)

(21) Appl. No.: 18/252,583

(22) PCT Filed: Nov. 5, 2021
(86) PCT No.: PCT/JP2021/040800

§ 371 Date: May 11, 2023

(30) Foreign Application Priority Data
Nov. 20, 2020 (JP) 2020-193097

(51) Int. Cl. H01L 27/146; H01L 21/66

(52) U.S. Cl. CPC H01L 27/14634; H01L 27/14636; H01L 27/1469; H01L 22/32

(57) ABSTRACT

The present disclosure relates to a solid-state imaging element, a manufacturing method, and an electronic apparatus capable of manufacturing more conforming products. A first semiconductor substrate is provided with a first pad used for connection with the outside, separately from a dedicated pad used for inspection in a manufacturing process. A second semiconductor substrate is provided with a second pad used for inspection in a manufacturing process. Then, when the first semiconductor substrate and the second semiconductor substrate are layered in units of chips after inspection for guaranteeing KGD is performed on each of the first semiconductor substrate and the second semiconductor substrate, the first pad and the second pad are electrically connected to each other via a first electrode provided in the first semiconductor substrate and a second electrode provided in the second semiconductor substrate. The present technology can be applied to a layered CMOS image sensor, for example.

### TECHNICAL FIELD

The present disclosure relates to a solid-state imaging element, a manufacturing method, and an electronic apparatus, and more particularly, to a solid-state imaging element, a manufacturing method, and an electronic apparatus capable of manufacturing more conforming products.

### BACKGROUND ART

Conventionally, a solid-state imaging element having a layered structure in which a plurality of semiconductor substrates is layered, is provided with a pad formed of aluminum or the like for electrical connection with the outside.

For example, Patent Document 1 discloses a solid-state imaging element having a three-layer structure, and shows a structure in which pads are arranged in the first and the third layers, or a structure in which pads are arranged in the second and the third layers.

### CITATION LIST

### Patent Document

Patent Document 1: WO 2018/186192 A

### SUMMARY OF THE INVENTION

### Problems to be Solved by the Invention

Meanwhile, conventionally, a manufacturing method has been adopted in which an inspection for guaranteeing a known good die (KGD) is performed for each semiconductor substrate before being layered, and only conforming products are bonded. However, for example, inspection pads are not provided for some semiconductor substrates. Therefore, it is not possible to perform the inspection for KGD on such semiconductor substrates, and it has been required to manufacture more conforming products.

The present disclosure has been made in view of such a situation, and an object of the present disclosure is to make it possible to manufacture more conforming products.

### Solutions to Problems

A solid-state imaging element according to an aspect of the present disclosure includes: a first semiconductor substrate provided with a first pad used for connection with the outside, separately from a dedicated pad used for inspection in a manufacturing process; and a second semiconductor substrate provided with a second pad used for inspection in a manufacturing process, in which the first pad and the second pad are electrically connected to each other via a first electrode provided in the first semiconductor substrate and a second electrode provided in the second semiconductor substrate.

A manufacturing method according to an aspect of the present disclosure is a manufacturing method of a solid-state imaging element including a first semiconductor substrate provided with a first pad used for connection with the outside, separately from a dedicated pad used for inspection in a manufacturing process, and a second semiconductor substrate provided with a second pad used for inspection in a manufacturing process, the method including electrically connecting the first pad and the second pad to each other via a first electrode provided in the first semiconductor substrate and a second electrode provided in the second semiconductor substrate.

An electronic apparatus according to an aspect of the present disclosure includes a solid-state imaging element including: a first semiconductor substrate provided with a first pad used for connection with the outside, separately from a dedicated pad used for inspection in a manufacturing process; and a second semiconductor substrate provided with a second pad used for inspection in a manufacturing process, in which the first pad and the second pad are electrically connected to each other via a first electrode provided in the first semiconductor substrate and a second electrode provided in the second semiconductor substrate.

According to an aspect of the present disclosure, a first semiconductor substrate is provided with a first pad used for connection with the outside, separately from a dedicated pad used for inspection in a manufacturing process, and a second semiconductor substrate is provided with a second pad used for inspection in a manufacturing process. Then, the first pad and the second pad are electrically connected to each other via a first electrode provided in the first semiconductor substrate and a second electrode provided in the second semiconductor substrate.

### BRIEF DESCRIPTION OF DRAWINGS

FIG. 1 is a block diagram illustrating a configuration example of a first embodiment of a solid-state imaging element to which the present technology is applied.

FIG. 2 is a diagram illustrating an example of an overall planar configuration of the solid-state imaging element.

FIG. 3 is a diagram illustrating a manufacturing method of the solid-state imaging element.

FIG. 4 is a block diagram illustrating a configuration example of a second embodiment of the solid-state imaging element to which the present technology is applied.

FIG. 5 is a block diagram illustrating a configuration example of an imaging device.

FIG. 6 is a diagram illustrating a usage example of using an image sensor.

### MODE FOR CARRYING OUT THE INVENTION

Hereinafter, specific embodiments to which the present technology is applied will be described in detail with reference to the drawings.

<First Configuration Example of Solid-State Imaging Element>

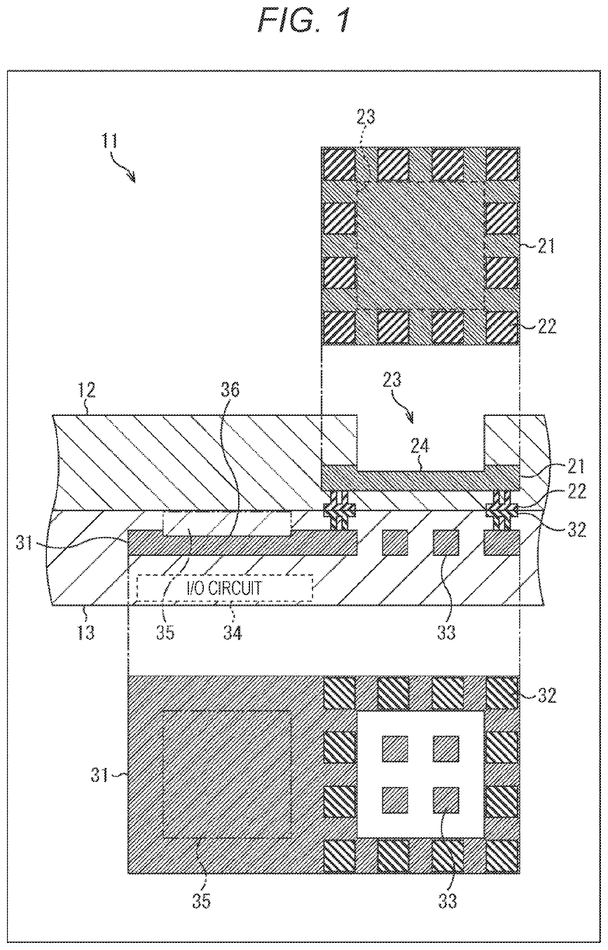

FIG. 1 is a diagram illustrating a configuration example of a first embodiment of a solid-state imaging element to which the present technology is applied.

A solid-state imaging element 11 illustrated in FIG. 1 is a semiconductor device (for example, a complementary metal oxide semiconductor (CMOS) image sensor) having a two-layer structure in which a sensor chip 12 that is a first semiconductor substrate and a logic chip 13 that is a second semiconductor substrate are layered. FIG. 1 illustrates an example of a partial cross-sectional configuration at a bonding portion that electrically bonds the sensor chip 12 and the logic chip 13.

In the sensor chip 12, for example, a plurality of pixels (not illustrated) for the solid-state imaging element 11 to perform imaging is provided, and an aluminum pad 21 and contact electrodes 22 are provided.

The aluminum pad 21 is used for wire bonding to electrically connect the solid-state imaging element 11 to the outside, and an opening 23 is formed in the sensor chip 12 so that the aluminum pad 21 is exposed. Furthermore, when the sensor chip 12 is dug to form the opening 23, a recess 24 corresponding to the shape of the opening 23 is formed in the aluminum pad 21. Note that the recess 24 has such a depth that the barrier metal of the aluminum pad 21 is scraped, for example.

The contact electrodes 22 are electrodes for electrically connecting the aluminum pad 21 to the logic chip 13, and are provided at a plurality of respective locations (12 locations in the example illustrated in FIG. 1) on the outer peripheral portion of the aluminum pad 21 outside the opening 23. For example, each of the contact electrodes 22 has an exposed surface on the surface of the sensor chip 12, which is the side to be bonded to the logic chip 13, and is formed by embedding a conductive material (for example, Cu or the like) in a trench dug from the exposed surface to the aluminum pad 21.

In the logic chip 13, for example, a logic circuit (not illustrated) for executing signal processing necessary for the solid-state imaging element 11 to perform imaging is provided, and an aluminum pad 31, contact electrodes 32, dummy patterns 33, and an I/O circuit 34 are provided.

The aluminum pad 31 is used for inspection for guaranteeing KGD for the logic chip 13. For example, in the inspection, an opening is provided for electrical connection to the aluminum pad 31, and a backfill portion 35 is provided by backfilling the opening after the inspection. Furthermore, when the logic chip 13 is dug to form the opening (not illustrated), a recess 36 corresponding to the shape of the opening is formed in the aluminum pad 31.

The aluminum pad 31 is also used for electrical connection with the sensor chip 12. For example, an opening region is formed in the aluminum pad 31 so as to correspond to the opening 23 formed in the sensor chip 12 in plan view, and the contact electrodes 32 are connected to a plurality of respective locations (12 locations in the example illustrated in FIG. 1) in the outer peripheral portion of the opening region.

The contact electrodes 32 are electrodes for electrically connecting the aluminum pad 31 to the sensor chip 12, and are provided at a plurality of respective locations corresponding to the contact electrodes 22 of the sensor chip 12. For example, the contact electrodes 32 are formed of the same material as that of the contact electrodes 22, and the contact electrodes 32 are electrically and mechanically connected to the respective contact electrodes 22 using bonding (Cu—Cu direct bonding) of the same material on each exposed surface.

The dummy patterns 33 are formed of the same aluminum material as that of the aluminum pad 31 so as to partially fill the opening region (that is, a region corresponding to the opening 23 of the sensor chip 12) formed in the aluminum pad 31. For example, the dummy patterns 33 are not electrically connected and do not have a function as wiring.

The I/O circuit 34 is a semiconductor circuit including a transistor, wiring, and the like configured to control input and output of a signal to and from the solid-state imaging element 11. For example, the I/O circuit 34 is arranged at a position other than the region corresponding to the opening 23 of the sensor chip 12, and is arranged so as to overlap the region where the recess 36 is formed in the aluminum pad 31 in plan view in the example illustrated in FIG. 1. That is, the I/O circuit 34 is preferably disposed so as not to be immediately below the wire bonding performed on the aluminum pad 21.

Note that the solid-state imaging element 11 has a structure in which the aluminum pad 21 of the sensor chip 12 and the aluminum pad 31 of the logic chip 13 are connected by Cu—Cu direct bonding between the contact electrodes 22 and the contact electrodes 32, but otherwise, bump bonding via solder may be used.

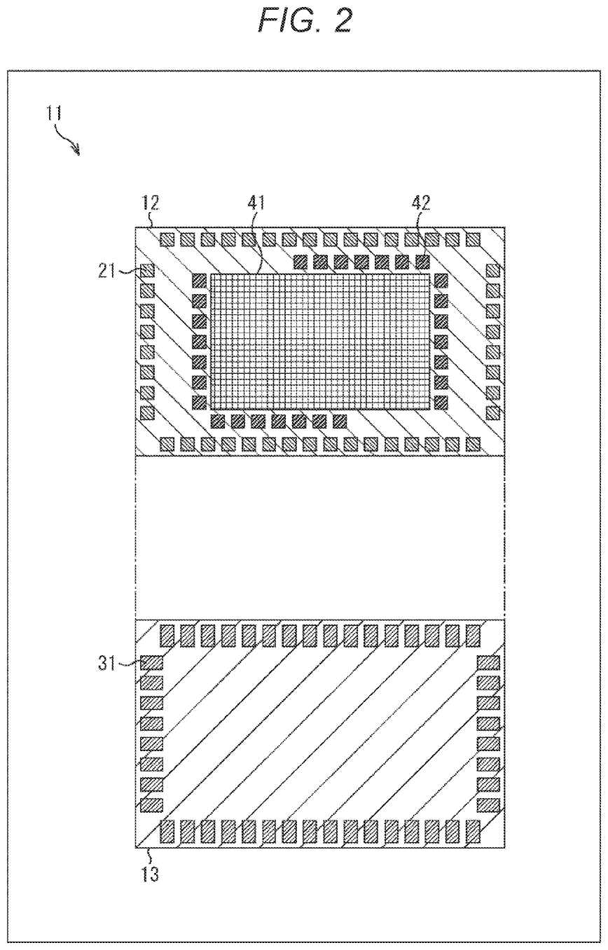

FIG. 2 illustrates an example of an overall planar configuration of the solid-state imaging element 11.

As illustrated in FIG. 2, the solid-state imaging element 11 is configured such that a plurality of the aluminum pads 21 provided along the outer periphery of the sensor chip 12 and a plurality of the aluminum pads 31 provided along the outer periphery of the logic chip 13 are arranged at corresponding positions. That is, the solid-state imaging element 11 is configured such that the aluminum pads 21 and the respective aluminum pads 31 are bonded as illustrated in FIG. 1 when the sensor chip 12 and the logic chip 13 are aligned and bonded in units of chips.

Furthermore, a pixel region 41 in which a plurality of pixels is arranged in an array is provided at the center of the sensor chip 12, and a plurality of KGD-dedicated pads 42 is provided in the vicinity of the pixel region 41. Note that an opening of each KGD-dedicated pad 42 is backfilled after an inspection for guaranteeing KGD for the sensor chip 12 is performed.

The solid-state imaging element 11 is configured as described above, and the sensor chip 12 is inspected for KGD using the KGD-dedicated pads 42, and the logic chip 13 is inspected for KGD using the aluminum pads 31. Then, the sensor chip 12 and the logic chip 13 given the inspection results representing conforming products are selected, and bonding using the contact electrodes 22 and the contact electrodes 32 is performed in units of chips. As described above, by inspecting both the sensor chip 12 and the logic chip 13 for KGD, more conforming products of the solid-state imaging element 11 can be manufactured as compared with the conventional manufacturing method.

With the configuration of the solid-state imaging element 11 in which the aluminum pads 21 for connection to the outside are provided in the sensor chip 12, the depth of the openings 23 can be made shallower as compared with the configuration in which an aluminum pad for connection to the outside is provided in the second layer or the third layer, for example. As a result, the solid-state imaging element 11 can have a structure that allows easy wire bonding on the aluminum pads 21.

In the solid-state imaging element 11, each of the openings 23 that opens the corresponding aluminum pad 21 of the sensor chip 12 and the corresponding backfill portion 35 (that is, the opening for inspecting the logic chip 13 for the KGD) of the logic chip 13 are arranged so as not to overlap each other in plan view. For example, the solid-state imaging element 11 has a layout in which the opening 23 and the backfill portion 35 are adjacent to each other in plan view. As a result, the solid-state imaging element 11 can reduce parasitic resistance and parasitic capacitance, for example.

The solid-state imaging element 11 has a layout in which each I/O circuit 34 is arranged at a position not overlapping the corresponding opening 23 in plan view, that is, the I/O circuit 34 overlaps the backfill portion 35 adjacent to the opening 23, for example. As a result, for example, the influence of wire bonding on the aluminum pad 21 does not reach the I/O circuit 34, and damage to the I/O circuit 34 can be avoided.

The solid-state imaging element 11 has a layout in which the dummy patterns 33 are arranged in the opening region which is formed in each aluminum pad 31 such that an area overlapping the opening 23 in plan view is opened. As described above, providing the dummy patterns 33 immediately below the opening 23 enables improvement in wire bond resistance of the solid-state imaging element 11 as compared with a structure in which the dummy patterns 33 are not provided, so that a more conforming product can be manufactured.

<Manufacturing Method of Solid-State Imaging Element>

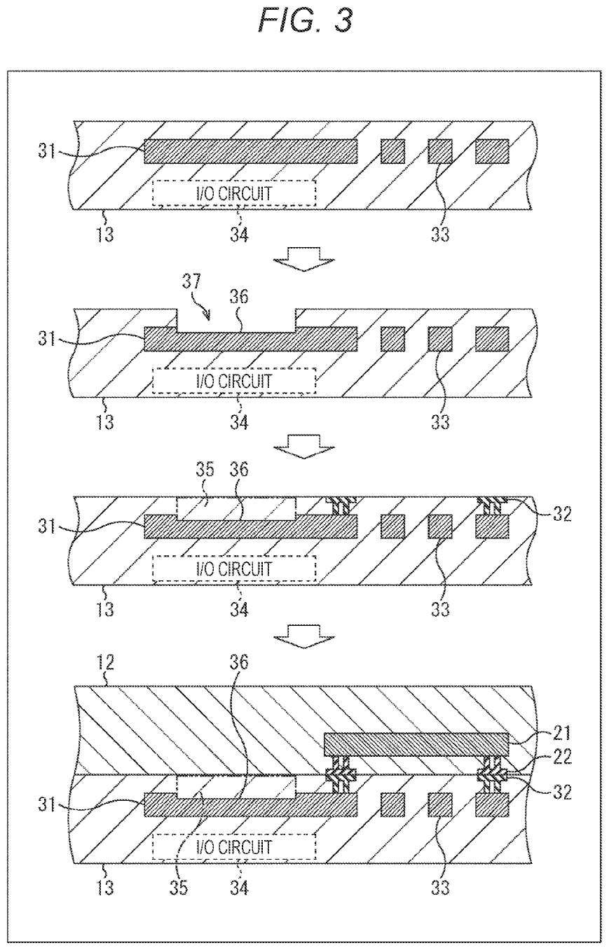

A manufacturing method of the solid-state imaging element 11 will be described with reference to FIG. 3.

In the first step, as illustrated in the first stage of FIG. 3, the aluminum pad 31 and the dummy patterns 33 are formed in a wiring layer of the logic chip 13.

In the second step, as illustrated in the second stage of FIG. 3, the wiring layer of the logic chip 13 is dug to form an opening 37 for performing KGD, and the aluminum pad 31 is partially opened. At this time, the recess 36 is formed in the aluminum pad 31 as the opening 37 is dug. Then, KGD inspection for the logic chip 13 is performed using the aluminum pad 31.

For example, in a case where the logic chip 13 is determined to be a conforming product as a result of the KGD inspection, in the third step, as illustrated in the third stage of FIG. 3, the backfill portion 35 is formed by backfilling the opening 37 with an insulator similar to an interlayer film of the wiring layer. Moreover, in order to form the contact electrodes 32, trenches are dug to embed a conductive material.

In the fourth step, as illustrated in the fourth stage of FIG. 3, the sensor chip 12 on which the aluminum pad 21 and the contact electrodes 22 have been formed and the KGD inspection has been performed in steps different from those of the logic chip 13 is layered on the logic chip 13 in units of chips. At this time, by Cu—Cu direct bonding between the contact electrodes 22 and the respective contact electrodes 32, the sensor chip 12 and the logic chip 13 are electrically and mechanically connected to each other.

Thereafter, for example, a step of partially opening the aluminum pad 21 by digging the wiring layer of the sensor chip 12 to form the opening 23 for wire bonding is performed, and the solid-state imaging element 11 is manufactured.

By the manufacturing method as described above, it is possible to manufacture the solid-state imaging element 11 that is a conforming product.

<Second Configuration Example of Solid-State Imaging Element>

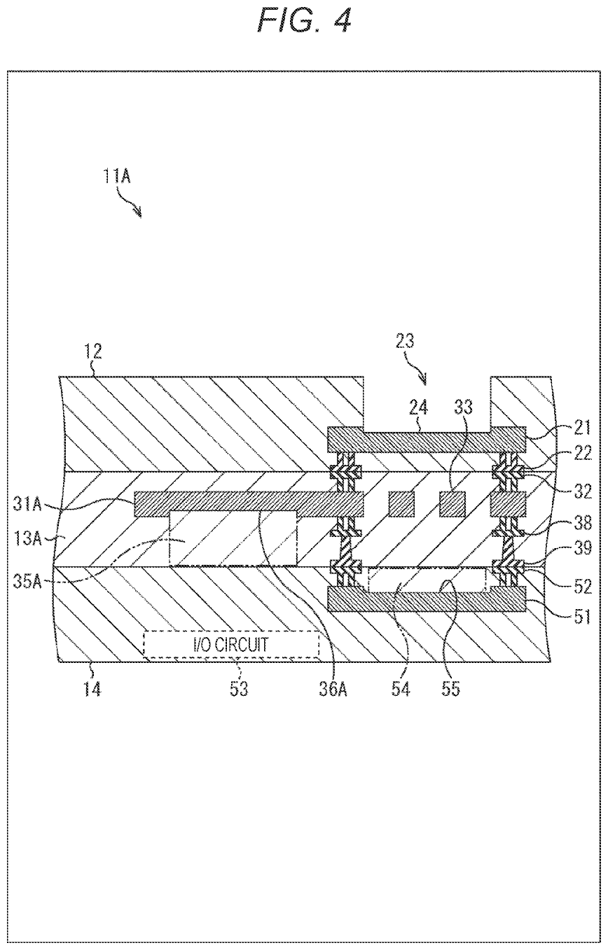

FIG. 4 is a diagram illustrating a configuration example of a second embodiment of the solid-state imaging element to which the present technology is applied. Note that, in a solid-state imaging element 11A illustrated in FIG. 4, configurations common to those of the solid-state imaging element 11 in FIG. 1 are denoted by the same reference numerals, and a detailed description thereof will be omitted.

As illustrated in FIG. 4, the solid-state imaging element 11A is a semiconductor device having a three-layer structure in which the sensor chip 12 that is a first semiconductor substrate, a logic chip 13A that is a second semiconductor substrate, and a memory chip 14 that is a third semiconductor substrate are layered. FIG. 4 illustrates an example of a partial cross-sectional configuration at a bonding portion that electrically bonds the sensor chip 12, the logic chip 13A, and the memory chip 14.

As illustrated in FIG. 4, in the logic chip 13A, a backfill portion 35A is formed on the memory chip 14 side, and accordingly, a recess 36A is formed in an aluminum pad 31A on the logic chip 13A side. Furthermore, in the logic chip 13A, contact electrodes 38 and 39 two-layer stacked for electrically connecting to the memory chip 14 are formed at a plurality of locations, and each contact electrode 39 has an exposed surface so as to be exposed on the surface of the logic chip 13A on the memory chip 14 side.

In the memory chip 14, for example, a memory (not illustrated) configured to temporarily store pixel data acquired by the sensor chip 12 is provided, and an aluminum pad 51, contact electrodes 52, and an I/O circuit 53 are provided.

The aluminum pad 51 is used for inspection for guaranteeing KGD for the memory chip 14. For example, in the inspection, an opening is provided for electrical connection to the aluminum pad 51, and a backfill portion 54 is provided by backfilling the opening after the inspection. Furthermore, when the memory chip 14 is dug to form the opening (not illustrated), a recess 55 corresponding to the shape of the opening is formed in the aluminum pad 51.

The aluminum pad 51 is also used for electrical connection with the logic chip 13A. For example, the contact electrodes 52 are connected to the aluminum pad 51 at a plurality of locations so as to correspond to the respective contact electrodes 39 of the logic chip 13A in plan view.

The contact electrodes 52 are electrodes for electrically connecting the memory chip 14 to the logic chip 13A, and are electrically and mechanically bonded using bonding (Cu—Cu direct bonding) of the same material on each exposed surface.

The I/O circuit 53 is a circuit including a transistor, wiring, and the like configured to control input and output of a signal to and from the solid-state imaging element 11A, and is preferably disposed so as not to be immediately below wire bonding applied to the aluminum pad 21.

The solid-state imaging element 11A is configured as described above, and a more conforming product can be manufactured similarly to the solid-state imaging element 11.

<Configuration Example of Electronic Apparatus>

The solid-state imaging element 11 as described above can be applied to various electronic apparatuses such as an imaging system such as a digital still camera or a digital video camera, a mobile phone having an imaging function, or another apparatus having an imaging function, for example.

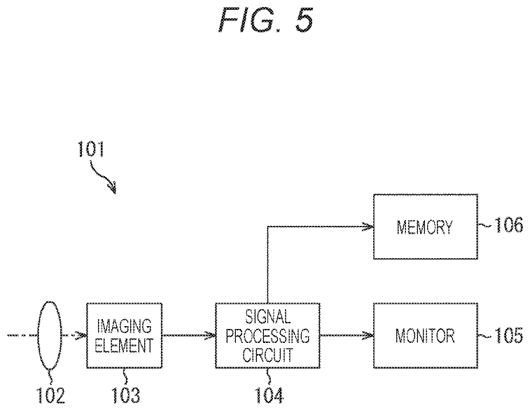

FIG. 5 is a block diagram illustrating a configuration example of an imaging device mounted on an electronic apparatus.

As illustrated in FIG. 5, an imaging device 101 includes an optical system 102, an imaging element 103, a signal processing circuit 104, a monitor 105, and a memory 106, and can capture a still image and a moving image.

The optical system 102 includes one or a plurality of lenses, guides image light (incident light) from a subject to the imaging element 103, and forms an image on a light receiving surface (sensor unit) of the imaging element 103.

As the imaging element 103, the above-described solid-state imaging element 11 is applied. Electrons are accumulated in the imaging element 103 for a certain period according to an image formed on the light receiving surface via the optical system 102. Then, a signal corresponding to the electrons accumulated in the imaging element 103 is supplied to the signal processing circuit 104.

The signal processing circuit 104 performs various types of signal processing on the pixel signal output from the imaging element 103. An image (image data) obtained by performing signal processing by the signal processing circuit 104 is supplied to and displayed on the monitor 105, or supplied to and stored (recorded) in the memory 106.

In the imaging device 101 configured as described above, by applying the above-described solid-state imaging element 11, for example, a solid-state imaging element 11 that is a more conforming product can be used, and an image can be reliably captured.

<Usage Example of Image Sensor>

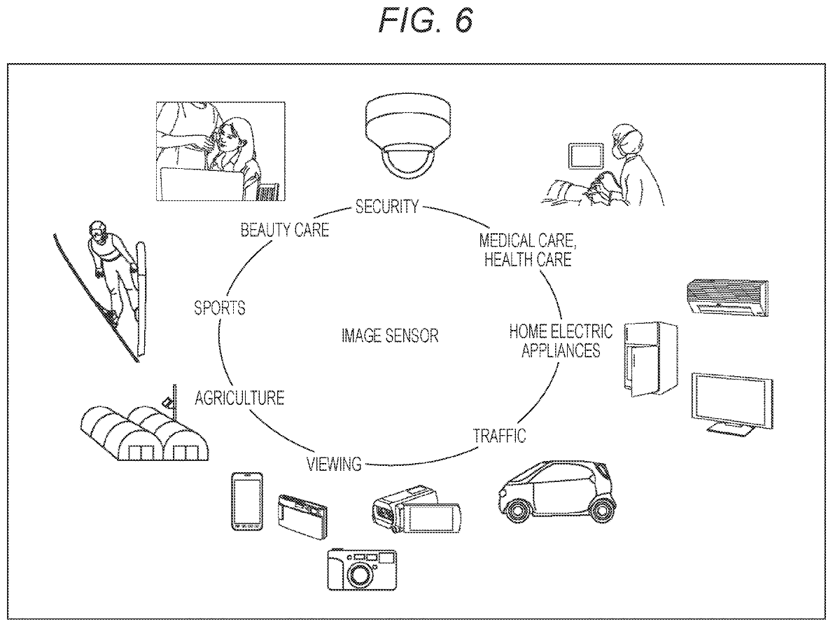

FIG. 6 is a diagram illustrating a usage example of using an image sensor (imaging element) described above.

The above-described image sensor can be used in various cases of sensing light such as visible light, infrared light, ultraviolet light, and X-rays as described below, for example.
A device, such as a digital camera or a mobile device with a camera function that captures an image to be used for viewing
A device used for traffic, such as an in-vehicle sensor that captures images of the front, rear, surroundings, inside, and the like of an automobile for safe driving such as automatic stop, recognition of a driver's condition, and the like, a monitoring camera that monitors traveling vehicles and roads, and a distance measuring sensor that measures a distance between vehicles and the like
A device used for home electric appliances, such as a TV, a refrigerator, and an air conditioner in order to capture an image of a gesture of a user and perform an apparatus operation according to the gesture
A device used for medical care or health care, such as an endoscope and a device that performs angiography by receiving infrared light
A device used for security, such as a monitoring camera for crime prevention and a camera for person authentication
A device used for beauty care, such as a skin measuring instrument for imaging skin and a microscope for imaging scalp
An apparatus used for sports, such as an action camera and a wearable camera for sports or the like
A device used for agriculture, such as a camera for monitoring conditions of fields and crops

<Combination Examples of Configurations>

Note that the present technology can also have the following configurations.

(1)

A solid-state imaging element including:
a first semiconductor substrate provided with a first pad used for connection with the outside, separately from a dedicated pad used for inspection in a manufacturing process; and
a second semiconductor substrate provided with a second pad used for inspection in a manufacturing process, in which
the first pad and the second pad are electrically connected to each other via a first electrode provided in the first semiconductor substrate and a second electrode provided in the second semiconductor substrate.

(2)

The solid-state imaging element according to (1) described above, in which the first semiconductor substrate and the second semiconductor substrate are layered in units of chips after inspection for guaranteeing known good die (KGD) is performed on each of the first semiconductor substrate and the second semiconductor substrate.

(3)

The solid-state imaging element according to (1) or (2) described above, in which
the first semiconductor substrate is provided with an opening for connecting the first pad to the outside,
the second semiconductor substrate is provided with a backfill portion obtained by backfilling a portion opened at a time of inspection using the second pad, and
the opening and the backfill portion are disposed at positions where the opening and the backfill portion do not overlap each other in plan view.

(4)

The solid-state imaging element according to (3) described above, in which
the second pad is formed with an opening region in which an area overlapping the opening in plan view is opened, and
a dummy pattern in which the opening is partially filled with the same material as a material of the second pad is provided.

(5)

The solid-state imaging element according to (3) or (4) described above, in which
the second semiconductor substrate is provided with a semiconductor circuit configured to control input and output of a signal, and
the semiconductor circuit is disposed at a position not overlapping the opening in plan view.

(6)

The solid-state imaging element according to (5) described above, in which the semiconductor circuit is disposed at a position overlapping the backfill portion in plan view.

(7)

The solid-state imaging element according to any one of (1) to (6) described above, in which the first electrode and the second electrode are electrically and mechanically connected to each other by using bonding of the same material.

(8)

The solid-state imaging element according to any one of (1) to (7) described above, further including:
a third semiconductor substrate provided with a third pad used for inspection in a manufacturing process, in which
the second pad and the third pad are electrically connected to each other via a second electrode provided in the second semiconductor substrate and a third electrode provided in the third semiconductor substrate.

(9)

A manufacturing method of a solid-state imaging element including a first semiconductor substrate provided with a first pad used for connection with the outside, separately from a dedicated pad used for inspection in a manufacturing process, and a second semiconductor substrate provided with a second pad used for inspection in a manufacturing process, the manufacturing method including:
electrically connecting the first pad and the second pad to each other via a first electrode provided in the first semiconductor substrate and a second electrode provided in the second semiconductor substrate.

(10)

An electronic apparatus including a solid-state imaging element, the solid-state imaging element including:
a first semiconductor substrate provided with a first pad used for connection with the outside, separately from a dedicated pad used for inspection in a manufacturing process; and
a second semiconductor substrate provided with a second pad used for inspection in a manufacturing process, in which
the first pad and the second pad are electrically connected to each other via a first electrode provided in the first semiconductor substrate and a second electrode provided in the second semiconductor substrate.

Note that the present embodiments are not limited to the above-described embodiments, and various modifications can be made in a range without departing from the gist of the present disclosure. Furthermore, the effects described in the present specification are merely examples and are not limited, and other effects may be provided.

### REFERENCE SIGNS LIST

11 Solid-state imaging element
12 Sensor chip
13 Logic chip
14 Memory chip
21 Aluminum pad
22 Contact electrode
23 Opening
24 Recess
31 Aluminum pad
32 Contact electrode
33 Dummy pattern
34 I/O circuit
Backfill portion
36 Recess
37 Opening
38 and 39 Contact electrode
41 Pixel region
42 KGD-dedicated pad
51 Aluminum pad
52 Contact electrode
53 I/O circuit
54 Backfill portion
55 Recess

What is claimed is:

1. A solid-state imaging element, comprising:
a first semiconductor substrate provided with a first pad used for connection with an outside, separately from a dedicated pad used for inspection in a manufacturing process; and
a second semiconductor substrate provided with a second pad used for inspection in a manufacturing process, wherein
the first pad and the second pad are electrically connected to each other via a first electrode provided in the first semiconductor substrate and a second electrode provided in the second semiconductor substrate.

2. The solid-state imaging element according to claim 1, wherein the first semiconductor substrate and the second semiconductor substrate are layered in units of chips after inspection for guaranteeing known good die (KGD) is performed on each of the first semiconductor substrate and the second semiconductor substrate.

3. The solid-state imaging element according to claim 1, wherein
the first semiconductor substrate is provided with an opening for connecting the first pad to the outside,
the second semiconductor substrate is provided with a backfill portion obtained by backfilling a portion opened at a time of inspection using the second pad, and
the opening and the backfill portion are disposed at positions where the opening and the backfill portion do not overlap each other in plan view.

4. The solid-state imaging element according to claim 3, wherein
the second pad is formed with an opening region in which an area overlapping the opening in plan view is opened, and
a dummy pattern in which the opening is partially filled with a same material as a material of the second pad is provided.

5. The solid-state imaging element according to claim 3, wherein
the second semiconductor substrate is provided with a semiconductor circuit configured to control input and output of a signal, and
the semiconductor circuit is disposed at a position not overlapping the opening in plan view.

6. The solid-state imaging element according to claim 5, wherein the semiconductor circuit is disposed at a position overlapping the backfill portion in plan view.

7. The solid-state imaging element according to claim 1, wherein the first electrode and the second electrode are electrically and mechanically connected to each other by using bonding of a same material.

8. The solid-state imaging element according to claim 1, further comprising:
a third semiconductor substrate provided with a third pad used for inspection in a manufacturing process, wherein
the second pad and the third pad are electrically connected to each other via a second electrode provided in the second semiconductor substrate and a third electrode provided in the third semiconductor substrate.

9. A manufacturing method of a solid-state imaging element including a first semiconductor substrate provided with a first pad used for connection with an outside, separately from a dedicated pad used for inspection in a manufacturing process, and a second semiconductor substrate provided with a second pad used for inspection in a manufacturing process, the manufacturing method comprising:
electrically connecting the first pad and the second pad to each other via a first electrode provided in the first semiconductor substrate and a second electrode provided in the second semiconductor substrate.

10. An electronic apparatus comprising a solid-state imaging element, the solid-state imaging element including:
a first semiconductor substrate provided with a first pad used for connection with an outside, separately from a dedicated pad used for inspection in a manufacturing process; and
a second semiconductor substrate provided with a second pad used for inspection in a manufacturing process, wherein
the first pad and the second pad are electrically connected to each other via a first electrode provided in the first semiconductor substrate and a second electrode provided in the second semiconductor substrate.
